(19) United States
(12) Patent Application Publication
(10) Pub. No.: US 2025/0248003 A1
(43) Pub. Date: Jul. 31, 2025

(54) THERMAL REGULATION SYSTEM FOR A BACK-UP SYSTEM FOR A DATA CENTER

(71) Applicant: OVH, Roubaix (FR)

(72) Inventors: Maxime LACHEVRE, Hem (FR); Youssef HAMIDI, Roubaix (FR)

(21) Appl. No.: 19/042,657

(22) Filed: Jan. 31, 2025

(30) Foreign Application Priority Data
Jan. 31, 2024 (EP) 24305175.2

(51) Int. Cl. H05K 7/20

(52) U.S. Cl. CPC H05K 7/20709

(57) ABSTRACT

A thermal regulation system for pre-heating a back-up system for a data center is disclosed. The thermal regulation system includes a heat transfer module with a first fluid conduit, circulating a first coolant fluid from the data center through the heat transfer module, and a second fluid conduit, circulating a second coolant fluid from the heat transfer module through the back-up system. The first fluid conduit and the second fluid conduit are thermally connected via the heat transfer module such that heat is transferred from the first coolant fluid to the second coolant fluid to the back-up system.

### CROSS REFERENCE

The present application claims priority to European Patent Appl. No. 24305175.2, filed Jan. 31, 2024 entitled “THERMAL REGULATION SYSTEM FOR A BACK-UP SYSTEM FOR A DATA CENTER”, the entirety of which is incorporated herein by reference.

### FIELD OF TECHNOLOGY

The present technology generally relates to thermal regulation systems for a back-up system, such as a back-up generator, associated with data centers.

### BACKGROUND

Data centers are specialized facilities designed to house and manage a large number of electronic equipment, such as servers, processors, etc. for the purpose of processing, storing, and transmitting data.

To ensure uninterrupted service and continuous operations, data centers rely on back-up systems, such as back-up generators, in case of electrical grid failures or other power disruptions. The start-up and performance of the back-up generators may be impacted by various weather conditions (e.g., cold weather conditions and/or climates). To mitigate impacts of weather on performance, back-up generators are equipped with a thermal regulation system to pre-heat the back-up generator's cooling system, ensuring the back-up generator can start and operate reliably. Typically, thermal regulation systems use coolant heaters, such as water coolant heaters, to regulate temperature of the back-up generator and are controlled through temperature sensors to raise and/or maintain a coolant temperature of approximately 40° C.

There is thus an interest in developing a system for thermal regulation of a back-up system associated with data centers.

### SUMMARY

The embodiments of the present disclosure are based on developers' understanding of the drawbacks associated with conventional thermal regulation systems associated with back-up systems, such as back-up generators and electric batteries.

Specifically, the developers have identified inefficiencies of conventional back-up systems which have incorporated therein closed loop thermal regulation systems. The thermal regulation of the back-up systems are powered by electricity, ranging between 4 kW to 18 kW, to raise and/or maintain a predetermined temperature. Typically, these systems include a heating element connected to an external power source (e.g., electrical grid).

Back-up generators commonly use coolant heaters, such as water coolant heater. A coolant fluid is circulated, in a closed loop, between the coolant heater and the back-up generator to regulate temperature of the back-up generator. Similarly, electric batteries use an electric heater to transfer heat to a coolant fluid which is circulated in a closed loop between the electric battery and the heater.

These thermal regulation systems are operated constantly during cooler seasons of the year, leading to significant power consumption resulting in higher operational costs and an increased environmental impact due to increased carbon emissions. Additionally, continuous operation of the thermal regulation system leads to increased wear and tear of the equipment which contributes to larger operational and capital expenditures to maintain, replace, and/or purchase new equipment. Moreover, these systems usually operate independently from other infrastructures within the data center which limits opportunities for integration, scalability, and energy efficiency improvements.

Broadly, the present disclosure provides a system for thermal regulation of a back-up system using thermal energy from a data center. Specifically, a thermal regulation system thermally connects a back-up system to a data center to transfer heat from the data center to the back-up system, thereby pre-heating the back-up system to a temperature required for proper operation and function. This mitigates the need for the back-up system to have its own dedicated closed-loop thermal regulation system which operates continuously. Therefore, in certain embodiments, power consumption is significantly reduced.

According to one aspect of the present technology, there is provided a thermal regulation system including a heat transfer module; a first fluid conduit circulating a first coolant fluid from the data center and through the heat transfer module; a second fluid conduit circulating a second coolant fluid through the heat transfer module and to the back-up system; and the first fluid conduit and the second fluid conduit are thermally connected via the heat transfer module such that heat is transferred from the first coolant fluid to the second coolant fluid to the back-up system.

In some embodiments, the thermal regulation system further includes at least one of a first fluid bypass system fluidly connected to the first fluid conduit for bypassing flow of the first coolant through the heat transfer module; and a second fluid bypass system fluidly connected to the second fluid conduit for bypassing flow of the second coolant through the heat transfer module.

In some embodiments, the thermal regulation system further includes a sensor operably connected to the second fluid conduit for detecting a fluid property of the second coolant fluid.

In some embodiments, the thermal regulation system further includes a pump fluidly connected to at least one of the first fluid conduit and the second fluid conduit.

In some embodiments, the heat transfer module includes a heat exchanger, the first fluid conduit configured to circulate the first coolant fluid through the heat exchanger and the second fluid conduit configured to circulate the second coolant fluid through the heat exchanger.

In some embodiments, the heat transfer module includes a first heat exchanger, the fluid conduit configured to circulate the first coolant fluid through the first heat exchanger; a second heat exchanger, the second fluid conduit configured to circulate the second coolant fluid through the second heat exchanger; an intermediate fluid conduit circulating an intermediate coolant fluid, the intermediate fluid conduit having: a first portion circulating the intermediate coolant fluid through the first heat exchanger; and a second portion circulating the intermediate coolant through the second heat exchanger; the first fluid conduit and the first portion of the intermediate fluid conduit are thermally connected via the first heat exchanger such that heat is transferred from the first fluid coolant to the intermediate coolant fluid flowing through the first portion; and the second fluid conduit and the second portion of the intermediate fluid conduit are thermally connected via the second heat exchanger such that heat is transferred from the second coolant fluid to the intermediate coolant fluid flowing through the second portion.

In some embodiments, the thermal regulation system further including the back-up system; and in response to the transfer of heat from the first coolant fluid to the second coolant fluid, the back-up system is pre-heated to a predetermined temperature.

In some embodiments, the back-up system is a back-up generator.

In some embodiments, the back-up system includes a back-up heat transfer module for transferring heat from the second coolant fluid to the back-up system.

In some embodiments, the back-up system does not have an independent thermal regulation system.

According to one aspect of the present technology, there is provided a kit for thermal regulation including the thermal regulation system as described above; a first connector configured to connect the thermal regulation system to the data center; and a second connector configured to connect the thermal regulation system to the back-up system.

According to one aspect of the present technology, there is provided a data center including the thermal regulation system as described above; the data center; and the back-up system electrically connected to the data center; in response to the transfer of heat from the first coolant fluid to the second coolant fluid, the back-up system is pre-heated to a predetermined temperature.

In some embodiments, the data center further includes a dry cooler fluidly connected to at least one of the data center and the thermal regulation system.

In some embodiments, the back-up system is a back-up generator.

In some embodiments, the back-up system does not have an independent thermal regulation system.

According to one aspect of the present technology, there is provided a data center system including a data center; a back-up system electrically connected to the data center; and a thermal regulation system for pre-heating the back-up system, the thermal regulation system thermally connecting the data center and the back-up system such that heat is transferred from the data center to the back-up system to pre-heat the back-up system to a predetermined temperature.

In some embodiments, the back-up system is a back-up generator.

In some embodiments, the data center system further includes a dry cooler fluidly connected to at least one of the data center and the thermal regulation system.

In some embodiments, the back-up system does not have an independent thermal regulation system.

According to one aspect of the present technology, there is provided a back-up system for a data center connectable to a thermal regulation system including a fluid conduit circulating a back-up system coolant fluid to pre-heat the back-up system to a predetermined temperature, and a back-up system heat transfer module thermally connected with the fluid conduit and thermally connectable with a cooling system of a data center; the back-up heat transfer module is configured to transfer heat transported by the cooling system of the data center to the back-up system coolant fluid of the fluid conduit of the back-up system.

In some embodiments, the back-up system is a back-up generator.

In some embodiments, the back-up system does not have an independent thermal regulation system.

In the context of the present specification, unless expressly provided otherwise, electronic equipment may refer, but is not limited to, “servers”, “electronic devices”, “operation systems”, “systems”, “computer-based systems”, “controller units”, “monitoring devices”, “control devices” and/or any combination thereof appropriate to the relevant task at hand.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

It must be noted that, as used in this specification and the appended claims, the singular form “a”, “an” and “the” include plural referents unless the context clearly dictates otherwise.

As used herein, the term “and/or” is to be taken as specific disclosure of each of the two specified features or components with or without the other. For example “A and/or B” is to be taken as specific disclosure of each of (i) A, (ii) B and (iii) A and B, just as if each is set out individually herein.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects, and advantages of embodiments of the present technology will become apparent from the following description, the accompanying drawings, and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a functional block diagram of a data center system with a thermal regulation system connected to a data center and a back-up system, in accordance with embodiments of the present disclosure;

FIG. 2 illustrates a functional block and circuit diagram of the thermal regulation system of FIG. 1 including a heat transfer module, in accordance with embodiments of the present disclosure;

FIG. 3 illustrates a functional block and circuit diagram of the thermal regulation system of FIG. 1 with the heat transfer module of FIG. 2, the thermal regulation system including a pump associated with a back-up system fluid circuit, in accordance with embodiments of the present disclosure;

FIG. 4 illustrates a functional block and circuit diagram of the thermal regulation system of FIG. 1 with the heat transfer module of FIG. 2, the thermal regulation system including sensors associated with a back-up system fluid circuit, in accordance with embodiments of the present disclosure;

FIG. 5 illustrates a functional block and circuit diagram of the thermal regulation system of FIG. 1 with an alternative embodiment of a heat transfer module, in accordance with embodiments of the present disclosure;

FIG. 6 illustrates a functional block and circuit diagram of the thermal regulation system of FIG. 1 with the heat transfer module of FIG. 5 including a pump associated with an intermediate fluid circuit and a pump associated with a back-up system fluid circuit, in accordance with embodiments of the present disclosure;

FIG. 7 illustrates a functional block and circuit diagram of the thermal regulation system of FIG. 1 with the heat transfer module of FIG. 5 including a pump and sensors associated with an intermediate fluid circuit, in accordance with embodiments of the present disclosure;

FIG. 8 illustrates a functional block and circuit diagram of the data center system of FIG. 1 including a first connector fluidly connecting the thermal regulation system to the data center and a second connector fluidly connecting the thermal regulation system to the back-up system, in accordance with embodiments of the present disclosure.

It should be noted that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remain within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future.

Data centers house many rack-mounted electronic equipment, such as servers, processors, etc. In use, electronic processing assemblies generate a significant amount of heat that is quelled or at least dissipated in order avoid electronic component failures and ensure continued efficient operation. To regulate and evacuate the heat generated by the electronic equipment, data centers typically implement heat management systems to transfer excess heat from electronic equipment to a coolant fluid circulating through the data center. Heat generated by the electronic equipment is transferred to the coolant fluid, raising the temperature of the coolant fluid while lowering the temperature of the electronic equipment. Typically, the warmed coolant fluid exits the data center where it circulates through a dry cooler which cools the coolant fluid using ambient air. The coolant fluid exits from the dry cooler and is re-circulated through the data center.

With these fundamental principles in place, we will now consider some non-limiting examples to illustrate various implementations of aspects of the present disclosure.

Broadly, embodiments of the present disclosure are directed to a thermal regulation system which uses the thermal energy expelled from data centers to regulate temperature of a back-up system, such as a back-up generator and/or a back-up electric battery. The thermal regulation system is thermally connected to the data center and the back-up system to allow for the transfer thermal energy.

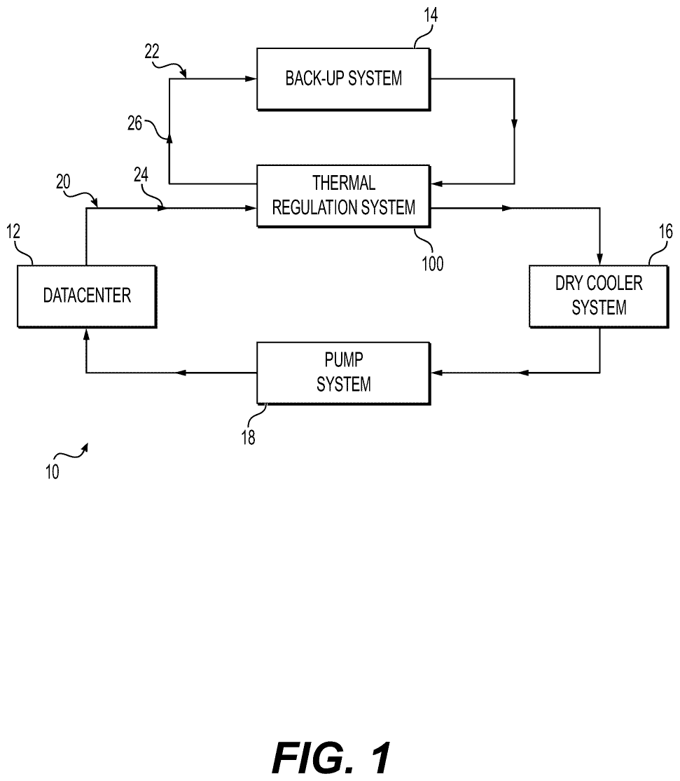

With reference to FIG. 1, a functional block diagram of a data center system 10 is depicted. The data center system 10 includes a data center 12 which houses electronic equipment such as servers, processors, etc. configured to process, store, and transmit data. The data center 12 includes a cooling system to circulate a data center coolant fluid 24 through the data center 12 to dissipate heat of the electronic equipment.

To ensure uninterrupted service and continuous operations, the data center system 10 includes a back-up system 14 electrically connected to the data center 12 to provide electricity in the event of an electrical grid failure and/or other power disruptions. In some embodiments, the back-up system includes at least one back-up generator. In other embodiments, the back-up system 14 may include at least one electric battery. It is appreciated that, in alternative embodiments, the back-up system 14 may include a combination of back-up generators and electric batteries.

The data center system 10 further includes a thermal regulation system 100 fluidly connected to the data center 12 and constitutes at least a portion of the cooling system of the data center 12. The thermal regulation system 100 is fluidly connected to the back-up system 14. The thermal regulation system 100 thermally connects the data center 12 with the back-up system 14 such that thermal energy is transferred between the data center 12 and the back-up system 14. Specifically, the thermal regulation system 100 facilitates heat management of the data center 12 and temperature control of the back-up system 14 by utilizing the heat generated by the electronic equipment of the data center 12 to raise and/or maintain a predetermined temperature of the back-up system 14, thereby mitigating impacts of cold weather conditions on the performance and operation of the back-up system 14. In some instances, the predetermined temperature is approximately 40° C. This means that a separate thermal regulation system for pre-heating and/or maintaining temperature of the back-up system 14 is not required. The thermal regulation system 100 will be described in further detail below. In some circumstances, the thermal regulation system 100 may be referred to as a heat recovery system.

The data center system 10 includes a dry cooler system 16 to further facilitate in heat management of the data center 12. The dry cooler system 16 includes at least one dry cooler assembly fluidly connected to the data center 12. Typically, a dry cooler assembly uses heat exchangers and fans to lower a temperature of the data center coolant fluid 24. Specifically, the data center coolant fluid 24 is received by the heat exchangers of the dry cooler assembly where the data center coolant fluid 24 transfers heat to ambient air, pulled in by the fans, thereby cooling the data center coolant fluid 24. The heated air is then discharged and the now cooled data center coolant fluid 24 is eventually recirculated back to the data center 12. It is contemplated that, in alternative embodiments, the dry cooler system 16 may be omitted.

The data center system 10 further includes a pump system 18 fluidly connected to the data center 12 and the dry cooler system 16 to facilitate circulation of the data center coolant fluid 24 between the dry cooler system 16 and the data center 12. It is contemplated that, in some embodiments, multiple pump systems 18 may be positioned along the data center fluid circuit 20 to facilitate circulation between the data center 12, the thermal regulation system 100, and the dry cooler system 16. It is contemplated that, in alternative embodiments, the pump system 18 may be omitted.

As depicted in FIG. 1, the data center system 10 includes a data center fluid circuit 20 and a back-up system fluid circuit 22. The data center fluid circuit 20 circulates the data center coolant fluid 24 between the data center 12, the thermal regulation system 100, the dry cooler system 16, and the pump system 18. The data center coolant fluid 24 may be a dielectric liquid or a non-dielectric liquid, for example and without limitation, water, glycol, oil, or a combination thereof. In this embodiment, the data center coolant fluid 24 is water.

The back-up system fluid circuit 22 circulates a back-up system coolant fluid 26 between the back-up system 16 and the thermal regulation system 100. The back-up system coolant fluid 26 may be a dielectric liquid or a non-dielectric liquid, for example and without limitation, water, glycol, oil, or a combination thereof. In this embodiment, the back-up system coolant fluid 26 is water. As depicted in FIG. 1, the back-up system fluid circuit 22 forms a closed loop circuit. In other words, the back-up system coolant fluid 26 flows from the back-up system 16 through the thermal regulation system 100 and returns to the back-up system 16. In alternative embodiments, the back-up system coolant fluid 26 may flow from a coolant source.

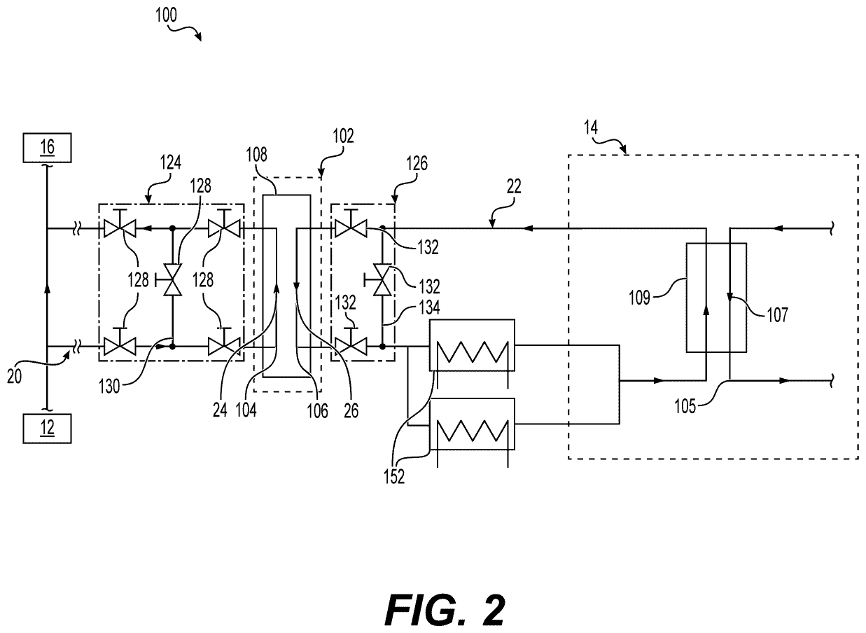

With reference to FIGS. 2 to 7, various embodiments of the thermal regulation system 100 will now be described in detail. The thermal regulation system 100 includes a heat transfer module 102 thermally connecting the data center 12 to the back-up system 14.

The thermal regulation system 100 includes a data center fluid conduit 104 positioned through the heat transfer module 102. The data center fluid conduit 104 constitutes at least a portion of the data center fluid circuit 20 such that the data center coolant fluid 24 circulates from the data center 12 through the heat transfer module 102 via the data center fluid conduit 104. The thermal regulation system 100 further includes a back-up system fluid conduit 106 positioned through the heat transfer module 102. The back-up system fluid conduit 106 constitutes at least a portion of the back-up system fluid circuit 22 such that the back-up system coolant fluid 26 circulates through the heat transfer module 102 to the back-up system 14 via the back-up system fluid conduit 106. The data center fluid conduit 104 and the back-up system fluid conduit 106 are thermally connected via the heat transfer module 102 and heat may be transferred from the data center coolant fluid 24 to the back-up system coolant fluid 26. The back-up system coolant fluid 26 is then circulated to the back-up system 14 to pre-heat and/or maintain the temperature of the back-up system 14 to the predetermined temperature.

As depicted in FIGS. 2 to 4, the heat transfer module 102 includes a liquid-to-liquid heat exchanger 108. In some embodiments, the heat exchanger 108 is a plate heat exchanger. The data center fluid conduit 104 is positioned through a first side of the heat exchanger 108 and the back-up system fluid conduit 106 is positioned through a second side of the heat exchanger 108 such that heat is transferred from the data center coolant fluid 24 to the back-up system coolant fluid 26.

During use, the data center coolant fluid 24 flows through the data center 12 where heat is transferred from the electronic equipment to the data center coolant fluid 24, lowering a temperature of the electronic equipment and raising the temperature of the data center coolant fluid 24. The data center coolant fluid 24 circulates from the data center 12 to the heat exchanger 108 via the data center fluid conduit 104. The data center coolant fluid 24 exits from the heat exchanger 108 and flows towards the dry cooler system 16.

The back-up system coolant fluid 26 circulates from the back-up system 14 to the heat exchanger 108. The back-up system coolant fluid 26 flows through the heat exchanger 108 via the back-up system fluid conduit 106. Upon exiting the heat exchanger 108, the back-up system coolant fluid 26 returns to the back-up system 14.

Within the heat exchanger 108, the back-up system coolant fluid 26 has a temperature lower than the temperature of the data center coolant fluid 24 (which has been raised by the electronic equipment within the data center 12). As a result, heat is transferred from the warmer data center coolant fluid 24 to the cooler back-up system coolant fluid 26 within the heat exchanger 108. Thus, the temperature of the data center coolant fluid 24 is lowered and the temperature of the back-up system coolant fluid 26 is raised.

The cooled data center coolant fluid 24 exits the heat exchanger 108 and flows through the dry cooler system 16 where the temperature may be further reduced before eventually being returned to the data center 12 to, once again, facilitate heat management of the electronic equipment.

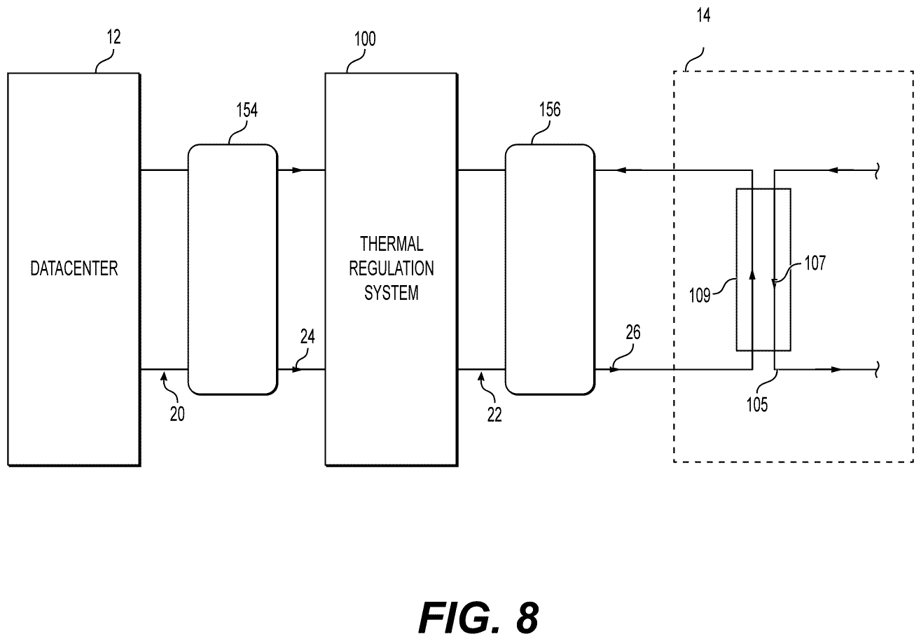

The warmed back-up system coolant fluid 26 exits the heat exchanger 108 and flows towards the back-up system 14. In some embodiments, the back-up system 14 includes an internal fluid conduit 105 for circulating an internal coolant fluid 107 (as depicted in FIGS. 2 and 8). The back-up system 14 may further include a back-up system heat transfer module 109, thermally connecting the back-up system 14 and the data center 12 via the thermal regulation system 100. The back-up heat transfer module 109 transfers heat from the back-up system coolant fluid 26 to the internal coolant fluid 105 which is then circulated through the back-up system 14 to pre-heat and/or maintain the back-up system 14 to the predetermined temperature. In some instances, the back-up system heat transfer module 109 may include a liquid-to-liquid heat exchanger, such as a plate heat exchanger.

In other embodiments, the back-up system heat transfer module may be omitted. Instead, the back-up system coolant fluid 26 may circulate through the back-up system 14 to facilitate in pre-heating and/or maintaining the temperature of the back-up system 14 to the predetermined temperature.

Exemplary temperatures along of the data center coolant fluid 24, as it flows through the data center fluid circuit 20 will now be presented. In certain embodiments, the data center coolant fluid 24 exits the data center 12 at a temperature of about 47° C. The data center coolant fluid 24 circulates from the data center 12 to the heat exchanger 108 of the thermal regulation system 100. As the data center coolant fluid 24 flows through the heat exchanger 108, heat is transferred from the data center coolant fluid 24 to the back-up system coolant fluid 26, where the data center coolant fluid 24 may experience a temperature change of up to 5° C. In one example, the data center coolant fluid 24 is about 43° C. upon exiting the heat exchanger 108. The data center coolant fluid 24 circulates from the heat exchanger 108 to the dry cooler system 16 where the temperature of the data center coolant fluid 24 is further reduced. Upon exiting the dry cooler system 16, a temperature of the data center coolant fluid 24 is about 27° C. before being circulated through the data center 12.

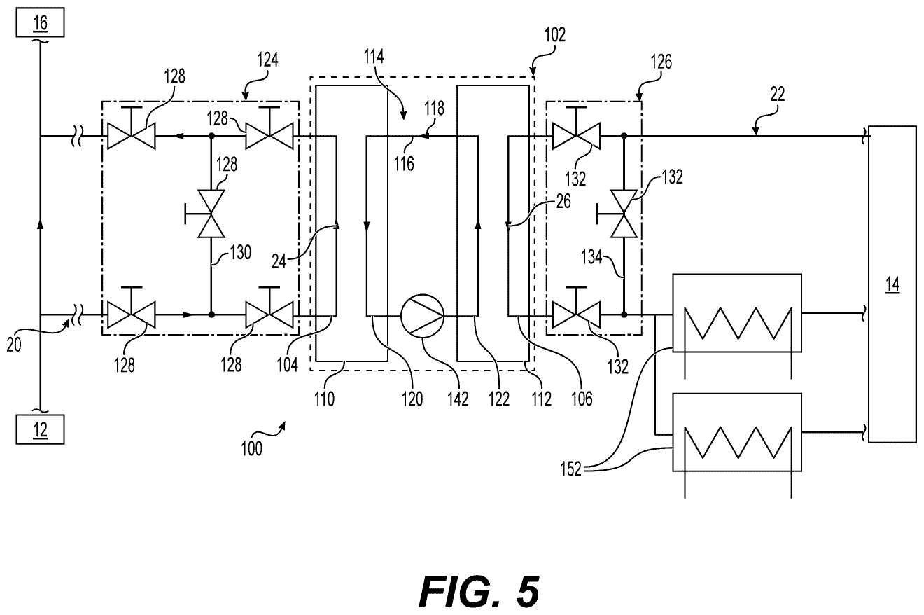

An alternative embodiment of the heat transfer module 102 is depicted in FIGS. 5 to 7. In this embodiment, the heat transfer module 102 includes a first liquid-to-liquid heat exchanger 110 and a second liquid-to-liquid heat exchanger 112 and an intermediate fluid circuit 114 therebetween. In some embodiments, each of the first heat exchanger 110 and the second heat exchanger 112 are heat exchanger plates. The intermediate fluid circuit 114 includes an intermediate fluid conduit 116 circulating an intermediate coolant fluid 118. The intermediate coolant fluid 118 may be a dielectric liquid or a non-dielectric liquid, for example and without limitation, water, glycol, oil, or a combination thereof. In this embodiment, the intermediate coolant fluid 118 is water. In some embodiments, the intermediate fluid circuit 114 is a closed loop circuit. In alternative embodiments, the intermediate fluid circuit 114 may be connected to a source for supplying the intermediate coolant fluid 118.

The data center fluid conduit 104 is positioned through a first side of the first heat exchanger 110 and a portion 120 of the intermediate fluid conduit 116 is positioned through a second side of the first heat exchanger 110. Thus, heat is transferred from the data center coolant fluid 24 to the intermediate coolant fluid 118 flowing through the portion 120 of the intermediate fluid conduit 116 positioned through the first heat exchanger 110.

A portion 122 of the intermediate fluid conduit 116 is positioned through a first side of the second heat exchanger 112 and the back-up system fluid conduit 106 is positioned through a second side of the second heat exchanger 112. Thus, heat is transferred from the intermediate coolant fluid 118 flowing through the portion 122 of the intermediate fluid conduit 116 positioned through the second heat exchanger 112 to the back-up system coolant fluid 26.

During use, the data center coolant fluid 24 flows through the cooling system of the data center 12 where heat is transferred from the electronic equipment to the data center coolant fluid 24, lowering a temperature of the electronic equipment and raising a temperature of the data center coolant fluid 24. The data center coolant fluid 24 circulates from the data center 12 to the first heat exchanger 110 via the data center fluid conduit 104. The data center coolant fluid 24 exits from the first heat exchanger 108 and flows towards the dry cooler system 16. The cooled data center coolant fluid 24 flows through the dry cooler system 16 where the temperature is further reduced. From the dry cooler system 16, the data center coolant fluid 24 is returned to the data center 12 to, once again, facilitate heat management of the electronic equipment.

Within the first heat exchanger 110, the temperature of the data center coolant fluid 24 is higher than a temperature of the intermediate coolant fluid 118 circulating through the first heat exchanger 110. As a result, heat is transferred from the warmer data center coolant fluid 24 to the cooler intermediate coolant fluid 118. The temperature of the data center coolant fluid 24 is lowered while the temperature of the intermediate coolant fluid 118 flowing through the portion 120 of the intermediate fluid conduit 116 is raised. The warmed intermediate coolant fluid 118 exits the first heat exchanger 110 and flows towards the second heat exchanger 112.

The back-up system coolant fluid 26 circulates from the back-up system 14 to the second heat exchanger 112. The back-up system coolant fluid 26 flows through the second heat exchanger 112 via the back-up system fluid conduit 106. Upon exiting the heat second exchanger 112, the back-up system coolant fluid 26 returns to the back-up system 14.

Within the second heat exchanger 112, the back-up system coolant fluid 26 has a temperature lower than the temperature of the intermediate coolant fluid 118 (which has been raised by the transfer of heat in the first heat exchanger 110). Heat is transferred from the warmer intermediate coolant fluid 118 to the cooler back-up system coolant fluid 26 within the second heat exchanger 112. As a result, the temperature of the intermediate coolant fluid 118 circulating through the portion 122 of the intermediate fluid conduit 116 is lowered while the temperature of the back-up system coolant fluid 26 is raised. Upon exiting the second heat exchanger 112, the cooled intermediate coolant fluid 118 flows towards the first heat exchanger 110.

The warmed back-up system coolant fluid 26 exits the second heat exchanger 112 and flows towards the back-up system 26. In some embodiments, the back-up system 14 includes an internal fluid conduit 105 for circulating an internal coolant fluid 107 (as depicted in FIGS. 2 and 8). The back-up system 14 may further include a back-up system heat transfer module 109, thermally connecting the back-up system 14 and the data center 12 via the thermal regulation system 100. The back-up heat transfer module 109 transfers heat from the back-up system coolant fluid 26 to the internal coolant fluid 107 which is then circulated through the back-up system 14 to pre-heat and/or maintain the back-up system 14 to the predetermined temperature. In some instances, the heat transfer module may include a liquid-to-liquid heat exchanger, such as a plate heat exchanger.

In other embodiments, the back-up system heat transfer module may be omitted. Instead, the back-up system coolant fluid 26 may circulate through the back-up system 14 to facilitate in pre-heating and/or maintaining the temperature of the back-up system 14 to the predetermined temperature.

The thermal regulation system 100 may further include a bypass system to bypass flow away from the heat transfer module 102. As depicted in FIGS. 2 to 7, the thermal regulation system 100 includes a first and a second bypass system 124, 126.

The first bypass system 124 is associated with the data center fluid circuit 20. Specifically, the first bypass system 124 is fluidly connected to the data center fluid conduit 104 to redirect flow of the data center coolant fluid 24. In some embodiments, the first bypass system 124 comprises at least one of: a bypass valve, a bypass pump, a bypass channel, a bypass sensor, and other bypass components which cooperate to alter the flow of the data center coolant fluid 24. For example, as depicted in FIGS. 2 to 7, the first bypass system 124 includes a plurality of bypass valves 128 disposed along the data center fluid conduit 104 and further includes the bypass channel 130 to divert flow away from the heat transfer module 102.

The second bypass system 126 is associated with the back-up system fluid circuit 22. Specifically, the second bypass system 126 is fluidly connected to the back-up system fluid conduit 106 to redirect flow of the back-up system coolant fluid 26. In some embodiments, the second bypass system 126 comprises at least one of: a bypass valve, a bypass pump, a bypass channel, a bypass sensor, and other bypass components which cooperate to alter the flow of the back-up system coolant fluid 26. For example, as depicted in FIGS. 2 to 7, the second bypass system 126 includes a plurality of bypass valves 132 disposed along the back-up system fluid conduit 106 and further includes the bypass channel 134 to divert flow away from the heat transfer module 102.

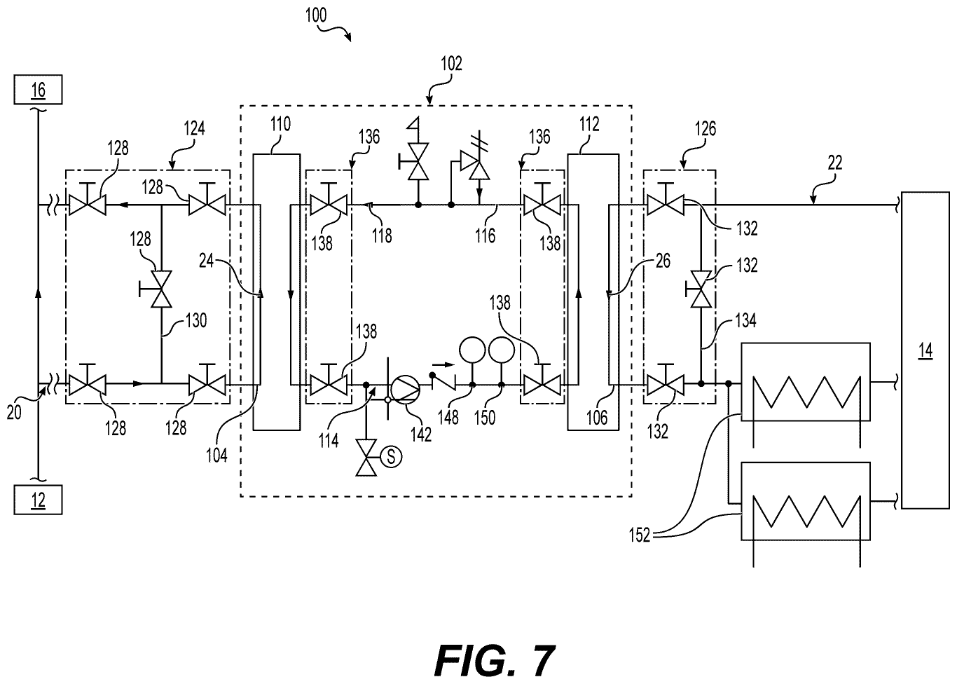

With specific reference to FIG. 7, the thermal regulation system 100 may further include an intermediate bypass system 136 associated with the intermediate fluid circuit 114 to redirect flow of the intermediate coolant fluid 118. In some embodiments, the intermediate bypass system 136 comprises of at least one of: a bypass valve, a bypass pump, a bypass channel, a bypass sensor, and other bypass components which cooperate to alter the flow of the intermediate system coolant fluid 118. For example, as depicted in FIG. 7, the intermediate bypass system 136 includes a plurality of bypass valves 138.

It is appreciated that the thermal regulation system 100 may include any number and any combination of the first bypass system 124, the second bypass system 126, and the intermediate bypass system 136 (if applicable). It is contemplated that, in alternative embodiments, the bypass systems 124, 126, 136 may be omitted.

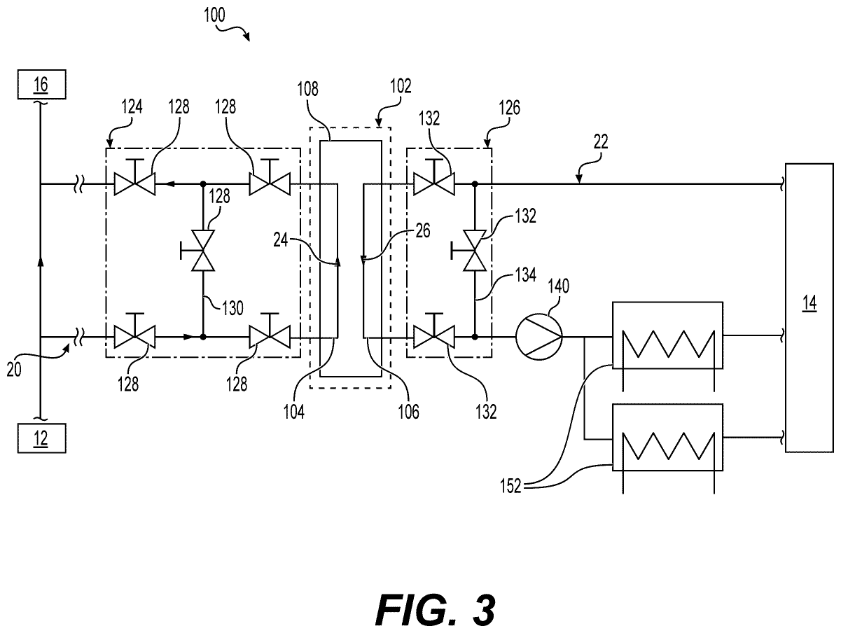

With reference to FIGS. 3, 5, 6, and 7, the thermal regulation system 100 may further include at least one pump to facilitate circulation through the associated fluid circuit.

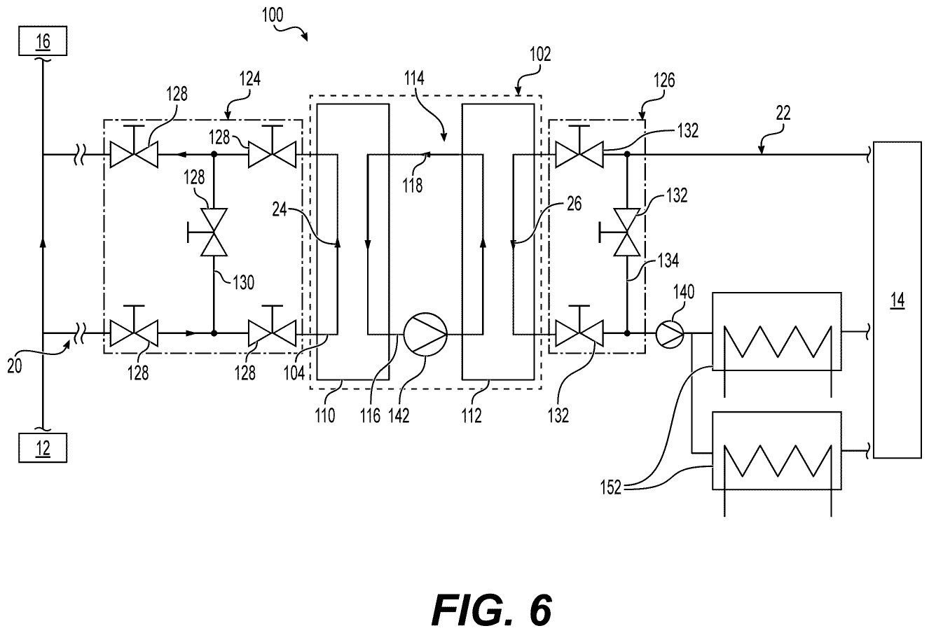

As depicted in FIGS. 3 and 6, the thermal regulation system 100 includes a pump 140 associated with the back-up system fluid circuit 22. The pump 140 is fluidly connected to the back-up system conduit 106 to facilitate circulation of the back-up system coolant fluid 26.

As depicted in FIGS. 5 to 7, the thermal regulation system 100 includes a pump 142 associated with the intermediate fluid circuit 114. The pump 142 is fluidly connected to the intermediate fluid conduit 116 to facilitate circulation of the intermediate coolant fluid 118.

It is contemplated that a pump may be associated with the data center fluid circuit 20 (not shown), fluidly connected to the data center fluid conduit 104, to facilitate circulation of the data center coolant fluid 24.

It is appreciated that the thermal regulation system 100 may include any number of and any combination of pumps associated with the data center fluid circuit 20, the back-up system fluid circuit 22, and the intermediate fluid circuit 114 (if applicable). It is contemplated that, in alternative embodiments, the pump(s) may be omitted.

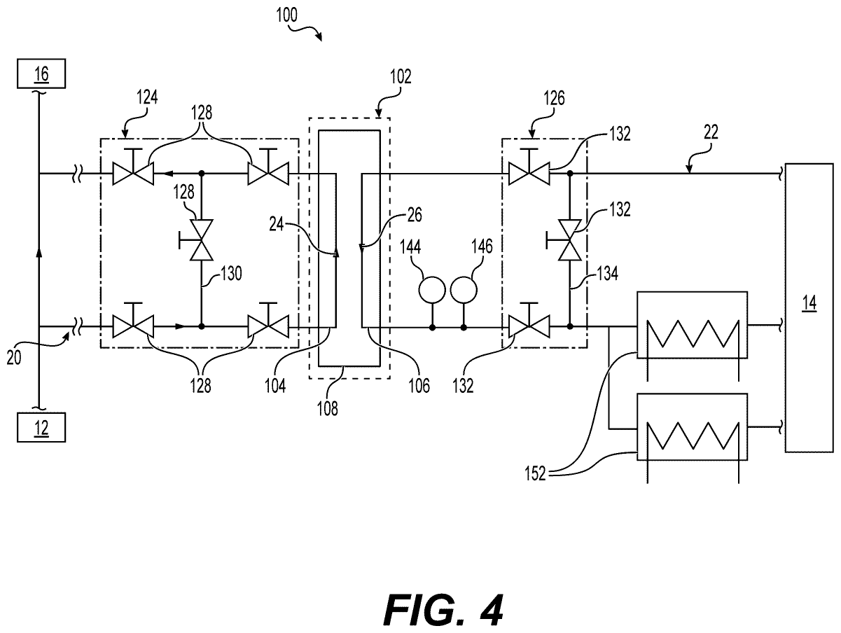

With reference to FIGS. 4 and 7, the thermal regulation system 100 includes a sensor to detect a fluid property of the respective coolant fluid. In some embodiments, the thermal regulation system 100 may include at least one of: a pressure sensor, a temperature sensor, a flow sensor, or any other sensor for detecting a fluid property of the respective coolant fluid.

As depicted in FIG. 4, the thermal regulation system 100 may also include a pressure sensor 144 and a temperature sensor 146 associated with the back-up system fluid circuit 22. The pressure sensor 144 is operably connected to the back-up system fluid conduit 106 for detecting a pressure of the back-up system coolant fluid 26. The temperature sensor 146 is operably connected to the back-up system fluid conduit 106 for detecting a temperature of the back-up system coolant fluid 26. In this embodiment, the pressure sensor 144 and the temperature sensor 146 are positioned downstream from the heat exchanger 108 and upstream from the back-up system 14 to detect the pressure and the temperature of the back-up system coolant fluid 26 upon exiting the heat exchanger 108. It is contemplated that, in alternative embodiments, the pressure sensor 144 and the temperature sensor 146 may be positioned anywhere along the back-up system fluid circuit 22. It is further contemplated that any type and any number of sensors may be operably connected to the back-up system fluid conduit 106 to detect the fluid properties of the back-up system coolant fluid 26.

As depicted in FIG. 7, the thermal regulation system 100 includes a pressure sensor 148 and a temperature sensor 150 associated with the intermediate fluid circuit 114. The pressure sensor 148 is operably connected to the intermediate fluid conduit 116 for detecting a pressure of the intermediate coolant fluid 118. The temperature sensor 150 operably connected to intermediate fluid conduit 116 for detecting a temperature of the intermediate coolant fluid 118. In this embodiment, the pressure sensor 148 and the temperature sensor 150 are disposed downstream from the first heat exchanger 110 and upstream from the second heat exchanger 112 to detect the pressure and the temperature of the intermediate coolant fluid 118 upon exiting the first heat exchanger 110. It is contemplated that, in alternative embodiments, the pressure sensor 148 and the temperature sensor 150 may be positioned anywhere along the intermediate fluid circuit 114. It is further contemplated that any type and any number of sensors may be operably connected to the intermediate fluid conduit 116 to detect the fluid properties of the intermediate coolant fluid 118.

Although not depicted, it is appreciated that any number and type of sensors may be associated with the data center fluid circuit 20 and operably connected to the data center fluid conduit 104 to detect fluid properties of the data center coolant fluid 24.

It is contemplated that the thermal regulation system 100 may utilize any combination of sensor(s), that is type and/or number, associated with the data center fluid circuit 20, the back-up system fluid circuit 22, and the intermediate fluid circuit 114 (if applicable). It is further contemplated that the sensor(s) may be omitted.

With reference to FIGS. 2 to 7, the thermal regulation system 100 further includes at least one electrical resistor 152 for further heating the temperature of the back-up system coolant fluid 26 upstream from the back-up system 14. It is appreciated that, in some embodiments, the electrical resistor 152 may be omitted.

In some embodiments, the thermal regulation system 100 includes a controller (not shown) communicatively connected to at least one of: the first bypass system 124, the second bypass system 126, and the intermediate bypass system 136 (if applicable). The controller may selectively actuate the respective bypass system 124, 126, 136 to redirect the flow of the respective fluid circuit 20, 22, 114. The controller may be configured to receive a signal from the sensors 144, 146, 148, 150 and based on the signal received by the controller, the controller may actuate the respective bypass system 124, 126, 136. In one specific example, with reference to the thermal regulation system 100 depicted in FIG. 4, the controller may receive a signal from the pressure sensor 144 and/or a signal from the temperature sensor 146. In response to the signal(s) received, the controller actuates the second bypass system 126 to redirect the back-up system coolant fluid 26 either towards or away from the heat transfer module 102.

In some embodiments, the controller is communicatively connected to at least one of the pump(s) 140, 142 associated with the back-up system fluid circuit 22, the intermediate fluid circuit 114 (if applicable), and the data center fluid circuit 20. The controller may selectively actuate the respective pump(s) 140, 142. The controller may be configured to receive a signal from the sensors 144, 146, 148, 150 and based on the signal received by the controller, the controller may actuate the respective pump(s) 140, 142.

In some embodiments, the controller is communicatively connected to the at least one electrical resistor 152. The controller may selectively actuate the electrical resistors 152 to further heat the back-up system coolant fluid 26 prior to circulating through the back-up system 14. The controller may be configured to receive a signal from the temperature sensor 146 associated with the back-up system fluid circuit 22 to detect the temperature of the back-up system coolant fluid 26. In response to receiving the signal, the controller may actuate the electrical resistors 152 to provide additional heating, if necessary.

It is contemplated that, in alternative embodiments, the controller may be omitted.

With reference to FIG. 8, the thermal regulation system 100 is connectable to the back-up system 14 via connectors 154, 156. The connectors 154, 156 may be configured to adapt to various back-up system configurations. In some embodiments, the connectors 154, 156 include a first connector 154 to connect the thermal regulation system 100 to the data center 12 and a second connector 156 to connect the thermal regulation system 100 to the back-up system 14. This enables the thermal regulation system 100 to be adaptable to various configurations of the back-up system 14, scalable for larger data centers 12, and enables retrofitting of older data center 12 and back-up system 14 configurations. In certain embodiments, the first and second connectors 154, 156 are ¾″ free nuts. It is contemplated that, in alternative embodiments, the first and second connectors 154, 156 may be any other size and/or other type of connector. Although the first and second connectors 154, 156 are described as being the same size and type of connector, it is appreciated that, in other embodiments, the first and second connectors 154, 156 may have different configurations from one another.

In some embodiments, the thermal regulation system 100 may be disposed within a container containing the back-up system 14 and the second connector 156 is connected to the back-up system 14. The first connector 154 may be positioned exterior of the container to connect to the thermal regulation system 100. Thus, the connectors 154, 156 fluidly connect the thermal regulation system 100 to the back-up system 14.

Although the thermal regulation system 100 has been described as transferring heat from the data center coolant fluid 24 to the back-up system coolant fluid 26 (thus, heating the back-up system coolant fluid 26 and cooling the data center coolant fluid 24), it is appreciated that the thermal regulation system 100 may instead provide cooling of the back-up system coolant fluid 26. In other words, within the heat transfer module 102, the back-up system coolant fluid 26 may have a higher temperature than the data center coolant fluid 24. Thus, heat may be transferred from the back-up system coolant fluid 26 to the data center coolant fluid 24, such that the temperature of the back-up system coolant fluid 26 is lowered and the temperature of the data center coolant fluid 24 is raised.

Although the various features of the thermal regulation system 100 have been described separately, it is appreciated that any combination of these features may be utilized, and the embodiments disclosed are exemplary.

As presented herein, the disclosed embodiments provide the thermal regulation system 100 of the back-up system 14 for the data center 12. The embodiments presented herein disclose thermally connecting the back-up system 14 with the cooling system of the data center 12. That is, the embodiments presented herein disclose using excess thermal energy from the data center 12 to pre-heat and/or maintain temperature of the back-up system 14. The thermal regulation system 100 includes the heat transfer module 102 to thermally connect the data center 12 and the back-up system 14. Specifically, the heat transfer module 102 facilitates transferring heat from the data center coolant fluid 24 to the back-up system coolant fluid 26. As disclosed herein, the back-up coolant fluid 26 may circulate through the back-up system thermal module 109 to transfer heat from the back-up coolant fluid 26 to the internal coolant fluid 107. In other words, the back-up system thermal module 109 thermally connects the back-up system 14 with the data center 12 via the thermal regulation system 100. Alternatively, the back-up system coolant fluid 26 may then circulate directly through the back-up system 14 to pre-heat and/or maintain the back-up system 14 to the predetermined temperature.

The disclosed embodiments of the thermal regulation system 100 provide various benefits including, but not limited to, a reduction in energy consumption by utilizing the excess thermal energy from the data center 12 which, in some instances, may reduce or eliminate the need for additional electrical heaters associated with the back-up system 14. The reduction in energy consumption may lead to significant cost savings in the data center 12 operating expenses (associated with the reduced energy consumption itself) and in capital expenditures (associated with reduced or eliminated need for maintaining, repair and/or providing additional electrical heaters). Additionally, the reduction in energy consumption reduces the carbon footprint of the data center 12, contributing to a greener data center operation. The adaptability of the thermal regulation system 100 to connect to various back-up systems 14 configurations via connectors 154,156 may provide users with the ability to scale the thermal regulation system 100 (allowing for the thermal regulation system 100 to accommodate data centers of different sizes and layouts), as well as the ability to retrofit existing data centers without requiring major infrastructure changes.

In view of the various disclosures directed to a thermal regulation system for a back-up system for a data center, it will be understood that, although the embodiments presented herein have been described with reference to specific features and structures, it is clear that various modifications and combinations may be made without departing from such disclosures. The specification and drawings are, accordingly, to be regarded simply as an illustration of the discussed implementations or embodiments and their principles as defined by the appended claims, and are contemplated to cover any and all modifications, variations, combinations or equivalents that fall within the scope of the present disclosure.

What is claimed is:

1. A thermal regulation system for pre-heating a back-up system for a data center, the back-up system configured to supply electrical power to the datacenter in case of an electrical power supply grid disruption, the system comprising:
a heat transfer module configured to thermally couple the back-up system to the datacenter;
a first fluid conduit circulating a first coolant fluid from the data center and through the heat transfer module;
a second fluid conduit circulating a second coolant fluid through the heat transfer module and to the back-up system; and
the first fluid conduit and the second fluid conduit are thermally connected via the heat transfer module such that heat is transferred from the first coolant fluid to the second coolant fluid for circulation to the back-up system.

2. The thermal regulation system of claim 1, further comprising at least one of:
a first fluid bypass system fluidly connected to the first fluid conduit for bypassing flow of the first coolant fluid through the heat transfer module; and
a second fluid bypass system fluidly connected to the second fluid conduit for bypassing flow of the second coolant fluid through the heat transfer module.

3. The thermal regulation system of claim 1, further comprising a sensor operably connected to the second fluid conduit for detecting a fluid property of the second coolant fluid.

4. The thermal regulation system of claim 1, wherein the heat transfer module comprises a heat exchanger, wherein the first fluid conduit configured to circulate the first coolant fluid through the heat exchanger and the second fluid conduit is configured to circulate the second coolant fluid through the heat exchanger.

5. The thermal regulation system of claim 1, wherein the heat transfer module comprises:
a first heat exchanger, wherein the first fluid conduit configured to circulate the first coolant fluid through the first heat exchanger;
a second heat exchanger, wherein the second fluid conduit is configured to circulate the second coolant fluid through the second heat exchanger;
an intermediate fluid conduit configured to circulate an intermediate coolant fluid, the intermediate fluid conduit having:
a first portion configured to circulate the intermediate coolant fluid through the first heat exchanger; and
a second portion configured to circulate the intermediate coolant through the second heat exchanger;
the first fluid conduit and the first portion of the intermediate fluid conduit are thermally connected via the first heat exchanger such that heat is transferred from the first fluid coolant to the intermediate coolant fluid flowing through the first portion; and
the second fluid conduit and the second portion of the intermediate fluid conduit are thermally connected via the second heat exchanger such that heat is transferred from the second coolant fluid to the intermediate coolant fluid flowing through the second portion.

6. The thermal regulation system of claim 1, wherein, in response to the transfer of heat from the first coolant fluid to the second coolant fluid, the back-up system is pre-heated by the transfer of heat to minimize the effects of cold weather conditions of back-up system performance.

7. The thermal regulation system of claim 6, wherein the back-up system is a back-up generator.

8. A kit for a thermal regulation system configured to pre-heat a datacenter back-up system, the kit comprising:
the thermal regulation system of claim 1;
a first connector configured to connect the thermal regulation system (100) to the data center; and
a second connector configured to connect the thermal regulation system to the back-up system.

9. A data center system comprising:
the thermal regulation system of claim 1;
the data center; and
the back-up system electrically connected to the data center;
wherein, in response to the transfer of heat from the first coolant fluid to the second coolant fluid, the back-up system is pre-heated to a predetermined temperature.

10. The data center system of claim 9, further comprising a dry cooler fluidly connected to at least one of the data center and the thermal regulation system.

11. A data center system comprising:
a data center;
a back-up system electrically connected to the data center; and
a thermal regulation system for pre-heating the back-up system, the thermal regulation system thermally connecting the data center and the back-up system such that heat is transferred from the data center to the back-up system to pre-heat the back-up system to a predetermined temperature.

12. The data center system of claim 11, wherein the back-up system is a back-up generator.

13. The data center system of claim 11, further comprising a dry cooler fluidly connected to at least one of the data center and the thermal regulation system.

14. The data center system of claim 11, wherein the back-up system does not have an independent thermal regulation system.

15. A back-up system for a data center connectable to a thermal regulation system, the back-up system comprising:
a fluid conduit circulating a back-up system coolant fluid to pre-heat the back-up system to a predetermined temperature, and
a back-up system heat transfer module thermally connected with the fluid conduit and thermally connectable with a cooling system of a data center; wherein:
the back-up heat transfer module is configured to transfer heat transported by the cooling system of the data center to the back-up system coolant fluid of the fluid conduit of the back-up system.
